(19) United States
(12) Patent Application Publication
(10) Pub. No.: US 2013/0001733 A1
(43) Pub. Date: Jan. 3, 2013

(54) SOLID-STATE IMAGING APPARATUS AND METHOD FOR MANUFACTURING SOLID-STATE IMAGING APPARATUS

(75) Inventor: Ryota WATANABE, Oita (JP)

(73) Assignee: Kabushiki Kaisha Toshiba, Tokyo (JP)

(21) Appl. No.: 13/422,918

(22) Filed: Mar. 16, 2012

(30) Foreign Application Priority Data
Jun. 29, 2011 (JP) 2011-144060

(51) Int. Cl. H01L 31/18; H01L 27/146

(52) U.S. Cl. 257/447; 438/73; 257/E27.13; 257/E31.11

(57) ABSTRACT

According to one embodiment, a method for manufacturing a solid-state imaging apparatus is provided. The method for manufacturing a solid-state imaging apparatus includes forming an element separating area separating photoelectric converting elements therebetween by epitaxially growing a semiconductor layer of a first conductivity type; and forming a charge accumulating area in the photoelectric converting element by epitaxially growing a semiconductor layer of a second conductivity type.

### CROSS-REFERENCE TO RELATED APPLICATIONS

This application is based upon and claims the benefit of priority from Japanese Patent Application No. 2011-144060, filed on Jun. 29, 2011; the entire contents of which are incorporated herein by reference.

### FIELD

Embodiments described herein relate generally to a solid-state imaging apparatus and a method for manufacturing a solid-state imaging apparatus.

### BACKGROUND

Conventionally, in a solid-state imaging apparatus, imaging is performed by accumulating charges photoelectrically converted by a plurality of photoelectric converting elements in charge accumulating areas of the respective photoelectric converting elements and reading out the charges from the charge accumulating areas.

In such a solid-state imaging apparatus, in a case where charges accumulated in the charge accumulating area of a photoelectric converting element leak to the charge accumulating area of another photoelectric converting element, quality of an imaged image is degraded. Thus, an element separating area is provided between the respective photoelectric converting elements to prevent the leakage of the charges.

Such an element separating area is formed, e.g., by ion-implanting and thermally diffusing impurities of a different conductivity type from those of the charge accumulating area in a border area between the photoelectric converting elements formed in a semiconductor substrate.

However, since a diffusion range of the impurities by the thermal diffusion is not uniform and differs with a depth position of the semiconductor substrate, parts with insufficient element separating characteristics exist in the element separating area formed by the ion implantation and the thermal diffusion.

### BRIEF DESCRIPTION OF THE DRAWINGS

FIG. 1 is a schematic diagram illustrating a cross-section of a solid-state imaging apparatus according to an embodiment;

FIG. 2 is a schematic cross-sectional view of the solid-state imaging apparatus according to the embodiment along the line A-A′ in FIG. 1;

FIG. 3 is a flowchart illustrating a manufacturing process of the solid-state imaging apparatus according to the embodiment; and

FIGS. 4 and 5 are schematic cross-sectional views illustrating the manufacturing process of the solid-state imaging apparatus according to the embodiment.

### DETAILED DESCRIPTION

In general, according to one embodiment, a method for manufacturing a solid-state imaging apparatus is provided. The method for manufacturing a solid-state imaging apparatus includes forming an element separating area separating photoelectric converting elements therebetween by epitaxially growing a semiconductor layer of a first conductivity type; and forming a charge accumulating area in the photoelectric converting element by epitaxially growing a semiconductor layer of a second conductivity type.

Exemplary embodiments of a solid-state imaging apparatus and a method for manufacturing a solid-state imaging apparatus will be explained below in detail with reference to the accompanying drawings. The present invention is not limited to the following embodiments. Hereinafter, a case in which a solid-state imaging apparatus is a backside illumination type CMOS (Complementary Metal Oxide Semiconductor) image sensor will be described.

It is to be noted that the solid-state imaging apparatus is not limited to a CMOS image sensor and may be an arbitrary image sensor in which an element separating area is provided between respective photoelectric converting elements such as a CCD (Charge Coupled Device).

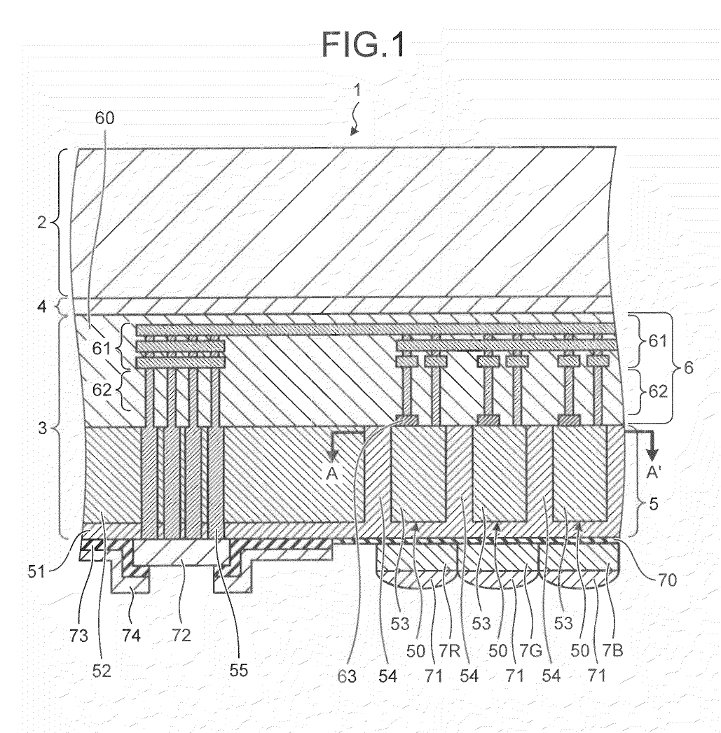

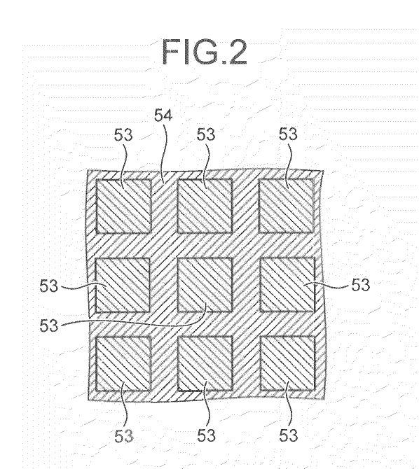

FIG. 1 is a schematic diagram illustrating a cross-section of a solid-state imaging apparatus 1 according to an embodiment, and FIG. 2 is a schematic cross-sectional view of the solid-state imaging apparatus 1 according to the embodiment along the line A-A′ in FIG. 1. As illustrated in FIG. 1, the solid-state imaging apparatus 1 includes a supporting substrate 2 and a device substrate 3 attached to the rear surface (lower surface) of the supporting substrate 2 via an attaching layer 4.

Also, the device substrate 3 includes a CMOS image sensor. Specifically, the device substrate 3 includes an element forming layer 5 and a multilayer wiring layer 6. The element forming layer 5 has a silicon epitaxial layer doped with impurities of a first conductivity type (P-type) (hereinafter referred to as “a first epi layer 51”) and a silicon epitaxial layer doped with impurities of a second conductivity type (N-type) (hereinafter referred to as “a second epi layer 52”).

In the solid-state imaging apparatus 1, a plurality of photodiodes 50, each formed by PN junction between the first epi layer 51 and the second epi layer 52 at a predetermined position of the device substrate 3, function as photoelectric converting elements.

Each photoelectric converting element has a charge accumulating area 53 accumulating charges photoelectrically converted by the photodiode 50. A plurality of charge accumulating areas 53 are made of the second epi layer 52 and are provided in a matrix form toward a light receiving surface as illustrated in FIG. 2.

Also, as illustrated in FIGS. 1 and 2, the respective charge accumulating areas 53 are electrically separated therebetween by an element separating area 54 made of the first epi layer 51. The element separating area 54 is formed, e.g., by pattern-etching the first epi layer 51 to be formed in a shape of the element separating area 54.

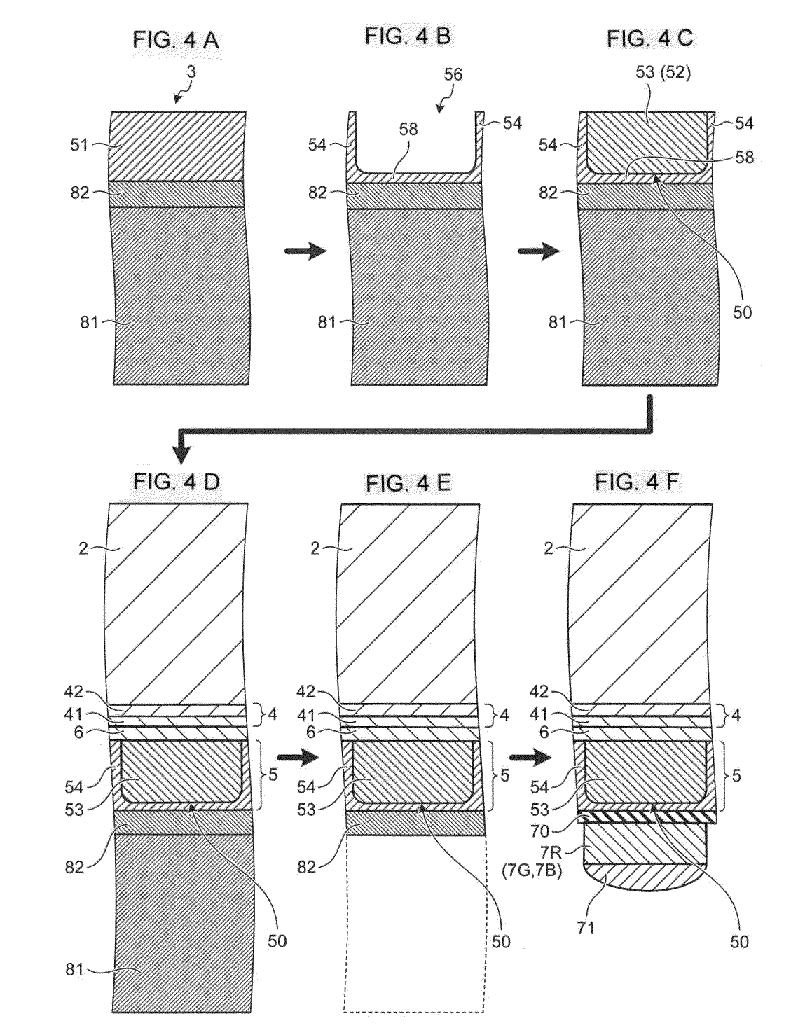

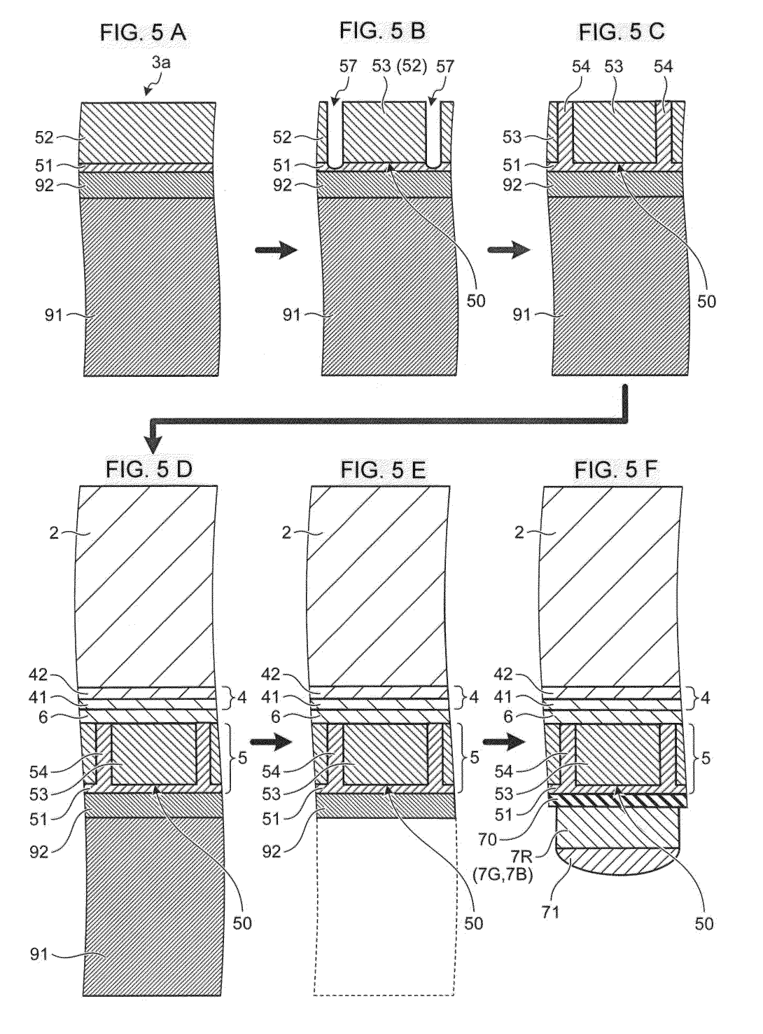

Alternatively, the element separating area 54 is formed by forming a recess at an area to form the element separating area 54 in the second epi layer 52 and epitaxially growing in the recess a semiconductor Layer doped with P-type impurities. Meanwhile, a process for forming the element separating area 54 will be described later in details with reference to FIGS. 4 and 5.

Also, on the rear surface of each photodiode 50 is provided a corresponding color filter 7R, 7G, or 7B of three primary colors via an antireflective film 70, and on the rear surface of each color filter 7R, 7G, or 7B is provided a microlens 71. In other words, in the solid-state imaging apparatus 1, three adjacent photodiodes 50 provided with the color filters 7R, 7G, and 7B of the three primary colors constitute one pixel.

Also, at a junction between the element forming layer 5 and the multilayer wiring layer 6 are provided corresponding to each photoelectric converting element a reading transistor, an amplifying transistor, a resetting transistor, and the like. Meanwhile, in FIG. 1, components of these transistors are not shown except gates 63 of the reading transistors.

The reading transistor is a transistor that is in an on state in a case of reading charges from the charge accumulating area 53. The amplifying transistor is a transistor that amplifies charges read from the charge accumulating area 53. The resetting transistor is a transistor that discharges charges accumulated in the charge accumulating area 53.

Also, in the element forming layer 5 is provided a through via 55 connecting an electrode pad 72 provided at a predetermined position of the rear surface thereof to the multilayer wiring layer 6. The electrode pad 72 is covered and protected at the circumferential portion of the bottom surface and the side surface with a passivation nitride film 73 and a passivation oxide film 74.

Also, the multilayer wiring layer 6 has a metal wiring layer 61 and a through via layer 62 provided in an interlayer insulating film 60. The metal wiring layer 61 is provided with metal wires in a multilayered manner. The through via layer 62 is provided with the plurality of through vias 55.

The electrode pad 72 and the aforementioned reading transistor, amplifying transistor, resetting transistor, and the like are connected via the through vias 55 in the element forming layer 5, the through vias 55 in the multilayer wiring layer 6, and the metal wires.

The solid-state imaging apparatus 1 performs imaging by the following operation. That is, the solid-state imaging apparatus 1 converts incident light from the microlenses provided on the rear surface into charges by the respective photodiodes 50 in accordance with light intensities and accumulates them in the charge accumulating areas 53.

The solid-state imaging apparatus 1 subsequently drives the reading transistors and the like based on predetermined control signals input in the electrode pad 72 from a control unit (not illustrated) and reads out the charges from the charge accumulating areas 53 for imaging.

As described above, the element separating area 54 of the solid-state imaging apparatus 1 is formed by etching the first epi layer 51 in a predetermined shape or by epitaxially growing in a recess formed by etching the second epi layer 52 a semiconductor layer doped with P-type impurities.

That is, in the solid-state imaging apparatus 1, the shape of the element separating area 54 is defined by etching. Thus, the width of the element separating area 54, that is to say, the distance between the charge accumulating areas 53 separated by the element separating area 54, is uniform regardless of the depth of each charge accumulating area 53 (position in a normal direction of the surface of the device substrate 3).

Accordingly, the element separating area 54 of the solid-state imaging apparatus 1 has greater element separating characteristics than an element separating area which is not uniform in width depending on the depth of the charge accumulating area 53, such as an element separating area formed by ion implantation and thermal diffusion of impurities.

In this manner, in the solid-state imaging apparatus 1, since the element separating characteristics of each photoelectric converting element are improved to enable to prevent charges accumulated in each charge accumulating area 53 from leaking to the adjacent charge accumulating area 53, quality degradation of an imaged image can be restricted.

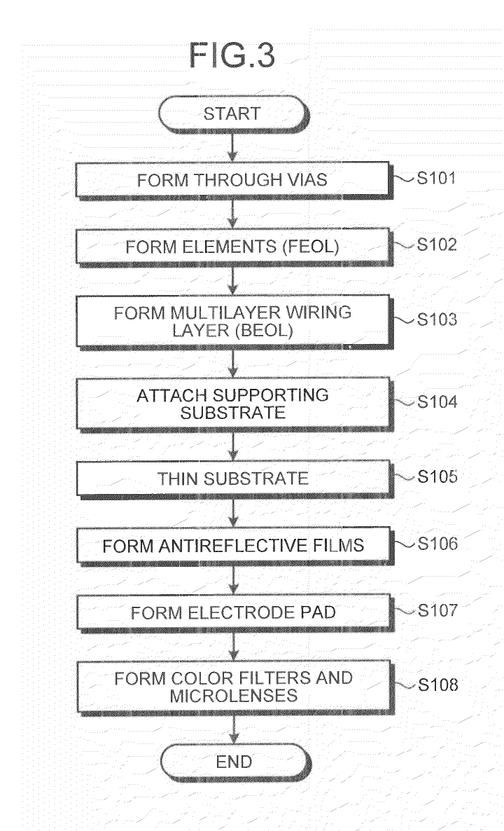

Next, a method for manufacturing the solid-state imaging apparatus 1 according to the embodiment will be described with reference to FIGS. 3 to 5. FIG. 3 is a flowchart illustrating a manufacturing process of the solid-state imaging apparatus 1 according to the embodiment, and FIGS. 4 and 5 are schematic cross-sectional views illustrating the manufacturing process of the solid-state imaging apparatus 1 according to the embodiment.

Hereinafter, a case of forming the element separating area 54 by etching the first epi layer 51 will be described with reference to FIGS. 3 and 4 while a case of forming the element separating area 54 by epitaxially growing in a recess formed by etching the second epi layer 52 a semiconductor layer doped with P-type impurities will be described with reference to FIG. 5. It is to be noted that, in FIGS. 4 and 5, the configuration of the multilayer wiring layer 6 is shown in a simplified manner.

In a case of forming the element separating area 54 by etching the first epi layer 51, as illustrated in (A) of FIG. 4, the device substrate 3 is first prepared in which, on a silicon sub substrate 81 doped with P-type impurities, are sequentially layered a silicon layer 82 doped with P-type impurities having one or more digits lower impurity concentration than that of the sub substrate 81 and the first epi layer 51 doped with P-type impurities.

Here, the device substrate 3 is prepared in which, on the silicon layer 82, is epitaxially grown the first epi layer 51 having a thickness of 3 μm or so and having boron concentration of 1e18/cm³ or higher, for example. It is to be noted that the impurities doped in the sub substrate 81 and the silicon layer 82 may be N-type. However, even in such a case, the impurity concentration of the silicon layer 82 shall be one or more digits lower than the impurity concentration of the sub substrate 81.

Subsequently, as illustrated in FIG. 3, the through vias 55 (refer to FIG. 1) are formed in the element forming layer 5 of the device substrate 3 (step S101), and a process of forming each element such as the photoelectric converting element (FEOL: Front End Of Line) is performed (step S102).

Specifically, after a resist film is formed on the first epi layer 51, the resist film except a part that becomes the element separating area 54 is removed from the first epi layer 51 with use of a photolithographic technique. Subsequently, an anisotropic dry etching such as an RIE (Reactive Ion Etching) is performed using the resist film as a mask to form a recess 56 in the first epi layer 51 as illustrated in (B) of FIG. 4.

In this manner, by performing the anisotropic dry etching to the first epi layer 51, the recess 56 extending in a direction parallel to a normal direction of a plate surface of the device substrate 3 can be formed. At this time, the RIE is performed so that the first epi layer 51 having a thickness of 0.1 μm or more may remain at the bottom portion of the recess 56.

In this manner, the element separating area 54 is formed by etching the first epi layer 51 with a bottom wall 58 and a side wall as the element separating area 54 remaining. It is to be noted that the recess 56 may be formed by a wet etching.

Subsequently, as illustrated in (C) of FIG. 4, the second epi layer 52 is epitaxially grown in a space formed by the bottom wall 58 and the side wall (element separating area 54) of the first epi layer 51 to form the charge accumulating area 53. By doing so, the photodiode 50 is formed by PN junction between the bottom wall 58 formed in the first epi layer 51 and the charge accumulating area 53 made of the second epi layer 52.

In this manner, in the present embodiment, the element separating area 54 is formed by forming the recess 56 by etching the first epi layer 51, and the charge accumulating area 53 is formed by epitaxially growing the second epi layer 52 in the recess 56.

Thus, in the present embodiment, the width of the element separating area 54, that is to say, the distance between the charge accumulating areas 53 separated by the element separating area 54, can be uniform regardless of the depth of each charge accumulating area 53 (position in a normal direction of the surface of the device substrate 3).

Accordingly, with the present embodiment, it is possible to form the element separating area 54 having greater element separating characteristics than an element separating area which is not uniform in width depending on the depth of the charge accumulating area 53, such as an element separating area formed by ion implantation and thermal diffusion of impurities.

Also, in the FEOL process, respective active areas for the reading transistor, the amplifying transistor, and the resetting transistor are formed at predetermined positions of the element forming layer 5 by a known manufacturing method.

Subsequently, as illustrated in FIG. 3, a process of forming the multilayer wiring layer 6 (BEOL: Back End Of Line) is performed (step S103). At this time, as illustrated in (D) of FIG. 4, the multilayer wiring layer 6 is formed on the element forming layer 5.

Subsequently, as illustrated in FIG. 3, the supporting substrate 2 is attached (step S104). Specifically, as illustrated in (D) of FIG. 4, the upper surface of the multilayer wiring layer 6 is heated to form an attaching layer 41 while the lower surface of the supporting substrate 2 is heated to form an attaching layer 42.

The heated attaching layers 41 and 42 then abut on each other to attach the device substrate 3 to the supporting substrate 2 (refer to FIG. 1). It is to be noted that the device substrate 3 and the supporting substrate 2 may be attached to each other by adhesive.

Subsequently, as illustrated in FIG. 3, the substrate is thinned (step S105). Specifically, as illustrated in (E) of FIG. 4, the sub substrate 81 is polished from the lower surface by a CMP (Chemical Mechanical Polishing). At this time, the CMP is performed so that the upper surface part of the sub substrate 81 may remain as thick as, e.g., 10 μm or more.

Subsequently, the remaining sub substrate 81 is removed by a selective wet etching. At this time, HF (hydrofluoric acid), HNO₃ (nitric acid), CH₃COOH (acetic acid), a mixed liquid of these, or KOH (potassium hydroxide) is used as etchant.

Here, since the silicon layer 82 has one or more digits lower impurity concentration than that of the sub substrate 81 as described above, the silicon layer 82 acts as an etching stopper at the time of the wet etching. Thus, the remaining sub substrate 81 is removed, and the rear surface of the silicon layer 82 is exposed (refer to (E) of FIG. 4). Subsequently, the silicon layer 82 is removed by a CMP or a dry etching in which the etching amount is specified to expose the bottom surface of the first epi layer 51.

In this manner, in the present embodiment, the silicon layer 82 acts as an etching stopper at the time of thinning the device substrate 3. Accordingly, with the present embodiment, the solid-state imaging apparatus 1 can be manufactured with lower cost than in a case of using as an etching stopper an expensive SOI substrate in which a BOX layer as an oxide layer is buried, for example.

Subsequently, as illustrated in FIG. 3, the antireflective films 70 are formed (step S106), the electrode pad 72 is formed (step S107), the color filters 7R, 7G, and 7B and the microlenses 71 are formed (step S108), to manufacture the solid-state imaging apparatus 1.

Specifically, as illustrated in (F) of FIG. 4, the antireflective film 70 is formed at an area corresponding to the photodiode 50 on the lower surface of the first epi layer 51, and the color filter 7R, 7G, or 7B is formed at a part corresponding to the photodiode 50 on the lower surface of the antireflective film 70. The microlens 71 is then formed on the lower surface of the color filter 7R, 7G, or 7B to manufacture the solid-state imaging apparatus 1.

Next, a case of forming the element separating area 54 by epitaxially growing in a recess 57 formed in the second epi layer 52 a semiconductor layer doped with P-type impurities will be described with reference to FIG. 5. In such a case, as illustrated in (A) of FIG. 5, a device substrate 3a is first prepared in which, on a silicon sub substrate 91 doped with P-type impurities, are sequentially layered a silicon layer 92 doped with P-type impurities having one or more digits lower impurity concentration than that of the sub substrate 91, the first epi layer 51 doped with P-type impurities, and the second epi layer 52 doped with N-type impurities.

Here, the device substrate 3a is prepared in which the first epi layer 51 having a thickness of 0.1 μm or so and having boron concentration of 1e18/cm³ or higher is epitaxially grown on the silicon layer 92, and in which the second epi layer 52 is epitaxially grown on the first epi layer 51, for example.

It is to be noted that the impurities doped in the sub substrate 91 and the silicon layer 92 may be N-type. However, even in such a case, the impurity concentration of the silicon layer 92 shall be one or more digits lower than the impurity concentration of the sub substrate 91.

Subsequently, as illustrated in (B) of FIG. 5, a recess 57 extending from the upper surface of the second epi layer 52 to the upper surface of the first epi layer 51 is formed at an area of the second epi layer 52 in which the element separating area 54 is intended to be formed.

At this time, the recess 57 is formed, e.g., by performing an anisotropic dry etching such as an RIE using as a mask a resist patterned in a predetermined shape with use of a photolithographic technique.

In this manner, by performing the anisotropic dry etching to the second epi layer 52, the recess 57 extending in a direction parallel to a normal direction of a plate surface of the device substrate 3a can be formed. It is to be noted that the recess 57 may be formed by a wet etching.

Here, an area surrounded by the recess 57 in the second epi layer 52 becomes the charge accumulating area 53. That is, the charge accumulating area 53 is formed by epitaxially growing the second epi layer 52 on the first epi layer 51. The photodiode 50 is formed by PN junction between the charge accumulating area 53 and the first epi layer 51.

Subsequently, as illustrated in (C) of FIG. 5, a silicon area doped with P-type impurities is epitaxially grown in the recess 57 to form the element separating area 54. In this manner, in the present embodiment, a semiconductor layer doped with P-type impurities is epitaxially grown in the recess 57 formed in the second epi layer 52 to form the element separating area 54 and the charge accumulating area 53.

Thus, in the present embodiment, the width of the element separating area 54, that is to say, the distance between the charge accumulating areas 53 separated by the element separating area 54, can be uniform regardless of the depth of each charge accumulating area 53 (position in a normal direction of the surface of the device substrate 3a).

Accordingly, with the present embodiment, it is possible to form the element separating area 54 having greater element separating characteristics than an element separating area which is not uniform in width depending on the depth of the charge accumulating area 53, such as an element separating area formed by ion implantation and thermal diffusion of impurities.

Subsequently, as illustrated in (D) of FIG. 5, after the multilayer wiring layer 6 is formed on the element forming layer 5, the upper surface of the multilayer wiring layer 6 is heated to form the attaching layer 41 while the upper surface of the supporting substrate 2 is heated to form the'attaching layer 42.

The heated attaching layers 41 and 42 then abut on each other to attach the device substrate 3a to the supporting substrate 2. It is to be noted that the device substrate 3a and the supporting substrate 2 may be attached to each other by adhesive.

Subsequently, as illustrated in (E) of FIG. 5, the sub substrate 91 is polished from the lower surface by a CMP. At this time, the CMP is performed so that the upper surface part of the sub substrate 91 may remain as thick as, e.g., 10 μm or more. Subsequently, the remaining sub substrate 91 is removed by a selective wet etching. Meanwhile, HF (hydrofluoric acid), HNO₃ (nitric acid), CH₃COOH (acetic acid), a mixed liquid of these, or KOH (potassium hydroxide) is used as etchant.

In this case as well, since the silicon layer 92 has one or more digits lower impurity concentration than that of the sub substrate 91, the silicon layer 92 acts as an etching stopper at the time of the wet etching. Thus, the remaining sub substrate 91 is removed, and the rear surface of the silicon layer 92 is exposed (refer to (D) of FIG. 5). Subsequently, the silicon layer 92 is removed by a CMP or a dry etching in which the etching amount is specified to expose the bottom surface of the first epi layer 51.

In this manner, in the present embodiment, the silicon layer 92 acts as an etching stopper at the time of thinning the device substrate 3a. Accordingly, with the present embodiment, the solid-state imaging apparatus 1 can be manufactured with lower cost than in a case of using as an etching stopper an expensive SOI substrate in which a BOX layer as an oxide layer is buried, for example.

Subsequently, as illustrated in (F) of FIG. 5, the antireflective film 70 is formed at an area corresponding to the photodiode 50 on the lower surface of the first epi layer 51, and the color filter 7R, 7G, or 7B is formed at a part corresponding to the photodiode 50 on the lower surface of the antireflective film 70. The microlens 71 is then formed on the lower surface of the color filter 7R, 7G, or 7B to manufacture the solid-state imaging apparatus 1.

As described above, in the present embodiment, the element separating area 54 is formed by etching the first epi layer 51. Alternatively, the element separating area 54 is formed by epitaxially growing in the recess 57 formed by etching the second epi layer 52 the semiconductor layer doped with P-type impurities.

Thus, in the solid-state imaging apparatus 1, the shape of the element separating area 54 is defined by etching. By doing so, the width of the element separating area 54 formed in the present embodiment, that is to say, the distance between the charge accumulating areas 53 separated by the element separating area 54, is uniform regardless of the depth of each charge accumulating area 53 (position in a normal direction of the surface of the device substrate 3a).

Accordingly, the element separating area 54 formed in the present embodiment has greater element separating characteristics than an element separating area which is not uniform in width depending on the depth of the charge accumulating area 53, such as an element separating area formed by ion implantation and thermal diffusion of impurities.

In this manner, in the solid-state imaging apparatus 1, since the element separating characteristics of each photoelectric converting element are improved to enable to prevent charges accumulated in each charge accumulating area 53 from leaking to the adjacent charge accumulating area 53, quality degradation of an imaged image can be restricted.

Also, in the method for manufacturing the solid-state imaging apparatus 1 according to the present embodiment, since ion implantation and thermal diffusion of impurities do not need to be performed to form the element separating area 54, it is possible to prevent the multilayer wiring layer 6 from being adversely affected by a thermal treatment at the time of the thermal diffusion of impurities.

Further, in the method for manufacturing the solid-state imaging apparatus 1 according to the present embodiment, since the element separating area 54 is formed by etching the first epi layer 51 or epitaxially growing the P-type semiconductor layer, the element separating area 54 extending from the upper surface to the lower surface of the charge accumulating area 53 can be formed. Accordingly, in the solid-state imaging apparatus 1, it is possible to prevent charges from leaking from any position in the depth direction of the charge accumulating area 53 to the adjacent charge accumulating area 53.

Still further, in the method for manufacturing the solid-state imaging apparatus 1 according to the present embodiment, since the width of the element separating area 54 can be formed to be a minimum required and uniform width regardless of the depth of the charge accumulating area 53, a light receiving area of the photodiode 50 can be enlarged.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a solid-state imaging apparatus, comprising:
forming an element separating area separating photoelectric converting elements therebetween by epitaxially growing a semiconductor layer of a first conductivity type; and
forming a charge accumulating area in the photoelectric converting element by epitaxially growing a semiconductor layer of a second conductivity type.

2. The method for manufacturing a solid-state imaging apparatus according to claim 1, wherein the element separating area is formed by epitaxially growing the semiconductor layer of the first conductivity type on a semiconductor substrate and thereafter etching the semiconductor layer of the first conductivity type with a bottom wall and a side wall as the element separating area remaining, and
wherein the charge accumulating area is formed by epitaxially growing the semiconductor layer of the second conductivity type in a space formed by the bottom wall and the side wall.

3. The method for manufacturing a solid-state imaging apparatus according to claim 2, wherein the etching is an anisotropic dry etching.

4. The method for manufacturing a solid-state imaging apparatus according to claim 2, wherein the semiconductor substrate includes a sub substrate doped with predetermined impurities and a semiconductor layer provided on an upper surface of the sub substrate and having one or more digits lower impurity concentration than that of the sub substrate.

5. The method for manufacturing a solid-state imaging apparatus according to claim 4, further comprising:
chemically and mechanically polishing the sub substrate from a lower surface and to make an upper surface part of the sub substrate remain.

6. The method for manufacturing a solid-state imaging apparatus according to claim 5, further comprising:
removing the upper surface part of the sub substrate by a wet etching.

7. The method for manufacturing a solid-state imaging apparatus according to claim 2, wherein the solid-state imaging apparatus is a backside illumination type image sensor.

8. The method for manufacturing a solid-state imaging apparatus according to claim 1, wherein the charge accumulating area is formed by epitaxially growing the semiconductor layer of the second conductivity type on the semiconductor layer of the first conductivity type formed on a semiconductor substrate, and
wherein the element separating area is formed by forming a recess extending from an upper surface of the semiconductor layer of the second conductivity type to the semiconductor layer of the first conductivity type at an area to form the element separating area in the semiconductor layer of the second conductivity type and epitaxially growing in the recess the semiconductor layer of the first conductivity type.

9. A solid-state imaging apparatus comprising:
a charge accumulating area provided in a recess formed in an epitaxial layer of a first conductivity type and made of an epitaxial layer of a second conductivity type; and
an element separating area separating photoelectric converting elements therebetween by a side wall of the recess.

10. The solid-state imaging apparatus according to claim 9, wherein the recess is formed by an anisotropic dry etching.

11. The solid-state imaging apparatus according to claim 9, wherein the solid-state imaging element is a backside illumination type image sensor.

12. A solid-state imaging apparatus comprising:
a charge accumulating area formed on a semiconductor layer of a first conductivity type and made of an epitaxial layer of a second conductivity type; and
an element separating area surrounding the charge accumulating area, provided in a recess extending from a surface of the epitaxial layer of the second conductivity type to the semiconductor layer of the first conductivity type, and made of an epitaxial layer of a first conductivity type separating photoelectric converting elements therebetween.

13. The solid-state imaging apparatus according to claim 12, wherein the recess is formed by an anisotropic dry etching.

14. The solid-state imaging apparatus according to claim 12, wherein the solid-state imaging apparatus is a backside illumination type image sensor.
